(19) United States
(12) Patent Application Publication
(10) Pub. No.: US 2007/0120268 A1
(43) Pub. Date: May 31, 2007

(54) Intermediate connection for flip chip in packages

(76) Inventors: Roland Irsigler, Muenchen (DE); Harry Hedler, Germering (DE); Bernd Goller, Otterfing (DE); Gerald Ofner, Mandarin Gdns (SG)

Correspondence Address: SLATER & MATSIL LLP, 17950 PRESTON ROAD, SUITE 1000, DALLAS, TX, 75252, US

(21) Appl. No.: 11/331,820

(22) Filed: Jan. 13, 2006

(30) Foreign Application Priority Data
Nov. 25, 2005 (DE) 10 2005 056 569.7

(51) Int. Cl. H01L 23/48

(52) U.S. Cl. 257/778

(57) ABSTRACT

An electronic component includes a substrate having contacts and a chip having contacts and a passivation layer disposed on an active side of the chip. The active side of the chip is mounted on a first surface of the substrate by flip chip technology such that the contacts of the chip are electrically connected to the contacts of the substrate by means of connecting elements. Elastic elevations are disposed between the contacts of the chip and the contacts of the substrate and an underfiller is disposed in an intermediate space between the chip and the substrate and between the elastic elevations. The underfiller and the elastic elevations have substantially the same modulus of elasticity.

This application claims priority to German Patent Application 10 2005 056 569.7 which was filed Nov. 25, 2005, and is incorporated herein by reference.

### TECHNICAL FIELD

The invention relates to an intermediate connection for flip chip in packages.

### BACKGROUND

In the case of such flip chip in packages (FCIP), the electrical connections between the contacts on the chip and the contact pads on the substrate are established by connecting elements in the form of solder bumps of a metal alloy (for example SnPb) by means of soldering. However, these quite rigid connecting elements do not ensure adequate mechanical connection between the chip and the substrate. For this reason, the gap between the chip and the substrate must be additionally filled with an adhesive (underfiller/underfilling material), in order that a good mechanical connection and adequate reliability in the temperature cycle test (TC −55/+125° C.) are ensured.

If the gap between the chip and the substrate is not underfilled, the different coefficients of thermal expansion (CTE) between the chip and the substrate cause such thermomechanical stresses in the solder bumps that the rigid soldered connection ruptures. This can be avoided by the underfiller, which generally has a high modulus of elasticity, which must typically be about 7-12 GPa, in order that the entire structure comprising the chip, connecting elements (solder bumps) and the substrate are rigidly connected to one another.

This solid connection is necessary in particular in the case of lead-free solder bumps, for example, of SnAg, SnAgCu, etc., since the solder bumps are less flexible than the conventional PbSn solder bumps. The modulus of elasticity is much higher for SinAg than it is for PbSn. Furthermore, the difference in the CTE between Pb-free solder bumps and the underfiller is greater than in the case of lead-containing eutectic solder bumps. The CTE in the case of Pb-free solder bumps of SnAg is ˜20-22 ppm, in the case of an underfiller ˜30-40 ppm and in the case of a lead-containing solder bumps of SnPb ˜24-28 ppm. This also leads to higher stresses at the interface between the underfiller and the low-k dielectric on the chip. A dielectric material is referred to as a low-k dielectric if it has a lower dielectric constant than the other insulating layers (SiO₂, Si₃N₄) that are used as intermediate layers for chip wiring interposers.

In the case of chips with a low-k dielectric, underfillers with a high modulus of elasticity often result in failures on account of damage (ruptures, delamination) in the low-k intermetallic dielectrics. The low-k layers cannot absorb the thermodynamic stresses transmitted from the rigid underfiller (also referred to as peeling stress) and come away. Flip chip in packages, comprising Pb-free connecting elements (solder bumps) and chips with a low-k dielectric, and optionally Cu metallization, cannot be reliably realized with the connecting technologies known from the prior art.

A solution to the problem is necessary, since, apart from improving the electrical properties, i.e., the parasitic characteristics R, L, C, by exchanging SiO₂ or SiNₓ, Al₂O₃, etc., as the dielectric for low-k materials such as black diamond and by exchanging wire bonding for flip chip connections, at the same time environmentally friendly production technologies are required, as a result of which lead-containing solder bumps (SnPb) must be replaced by lead-free solder bumps (SnAg, SnAgCu).

In the meantime, elastic bumps have also become known for use as connecting elements, but can only be used to a pitch of about 250 μm. Examples of such connecting elements are given in German Patent Nos. DE 102 41 589 A1, DE 102 58 093 B3 and DE 103 18 074 A1, and corresponding U.S. counterparts U.S. Pat. No. 6,919,264, and U.S. Patent Publication Nos. 2004/0135252 and 2004/4259290, each of which are incorporated herein by reference. With a pitch of 100 μm, for example, these connecting elements are not suitable because of the smaller dimensions that are then necessary and the resultant smaller contact areas, and consequently overall lower strength of the connection.

Furthermore, prefabricated polymer balls with a metal coating (polymer core solder balls), with which chips can be mounted on printed circuit boards, have also become known as a replacement for solder balls. The handling and mounting of such coated polymer balls is very laborious and they cannot be used with a pitch of 100 μm or less.

### SUMMARY OF THE INVENTION

In one aspect, the invention provides an intermediate connection for flip chip in packages in which the difficulties of the prior art are reliably overcome.

In one embodiment, the invention uses flexible elevations (polymer pillar bumps) as a Pb-free connecting element for the flip chip connection between the chip and the substrate and a correspondingly adapted underfiller. The modulus of elasticity in the underfiller can be reduced, whereby transmission of the thermomechanical stresses to the low-k layer can be prevented.

The flexible elevations with a pitch of about 100 μm in a height range of between 30 and 120 μm and a diameter of 20-80 μm can be produced by various methods, such as printing (screen printing or jet printing), photolithographic patterning, molding, P & P (pickup and place) prefabricated structures and other suitable methods.

As materials, polymer materials, such as polyimide, silicone, SU8 and other materials with a modulus of elasticity in the range <1-5 GPa come into consideration. SU8 is a high-contrast photoresist based on epoxy resin. The flexible elevation (polymer pillar bump) is subsequently coated fully or partly with a metal layer, for example by sputtering, electroplating or currentless coating or some other suitable method. The metallization on the flexible elevation with a thickness of around 3-5 μm in this case establishes the electrical connection with at least one pad of the chip.

The patterning of the metal layer on the elevation may in this case take place for example by means of an ED-resist (electrophoretic photoresist) process. Optionally, the metal layer may also be partly covered by a further top layer, which acts as a solder resist layer. This top layer may be created by wet-chemical methods (spray painting, ED-resist, etc.) or else by means of CVD methods.

The upper side of the flexible elevation may also be additionally provided with a solder depot, which can be produced electrochemically (electroplating) or by a printing process. The volume of solder is in this case generally much less than the volume of the flexible elevation.

Alternatively, the flexible elevations may also consist of polymer materials made conductive with conductive particles.

It is preferred for the flexible elevation also to be formed as a conically tapering truncated cone, facilitating the subsequent metallization and patterning.

Furthermore, the modulus of elasticity of the flexible elevation and of the underfiller are made to match one another in such a way as to compensate for the different CTE between the substrate and the chip without the transmitted stress at the interface between the underfiller and the low-k layer damaging the latter and, at the same time, the flexible elevation being flexible enough that no bump cracks occur.

### BRIEF DESCRIPTION OF THE DRAWINGS

The invention is to be explained in more detail below on the basis of an exemplary embodiment. In the associated figures of the drawing:

FIG. 1 shows a schematic representation of a chip which is provided with flexible elevations according to the invention (polymer pillar bumps) and a low-k dielectric, which are electrically connected by means of interconnects in each case to the associated pad on the chip, before the flip chip mounting;

FIG. 2 shows the chip as shown in FIG. 1 after the flip chip mounting on an FBGA substrate, an underfiller being introduced between the chip and the substrate to realize an adequate mechanical connection;

FIG. 3 shows a detail of the chip with a flexible elevation, which is provided with a metallization;

FIG. 4 shows the flexible elevation as shown in FIG. 2, which is additionally provided with a solder depot;

FIG. 5 shows a plan view of a fully metallized flexible elevation with an adjoining interconnect on the chip;

FIG. 6 shows a plan view of a partly metallized flexible elevation with an adjoining interconnect on the chip;

FIG. 7 shows a schematic representation of a process flow for producing the flexible elevations and the final assembly to form a flip chip in package; and

FIG. 8 shows a flow chart of a process flow for producing the flexible elevations and the final assembly to form a flip chip in package.

The following list of reference symbols can be used in conjunction with the figures:
1 chip 8 solder depot

2 flexible elevation/polymer pillar bump 9 substrate
3 passivation layer 10 contact pads/soldered connection
4 metallization 11 contact ball
5 interconnect 12 underfiller/underfilling compound
6 pad 13 mold/encapsulating compound
7 solder resist layer

### DETAILED DESCRIPTION OF ILLUSTRATIVE EMBODIMENTS

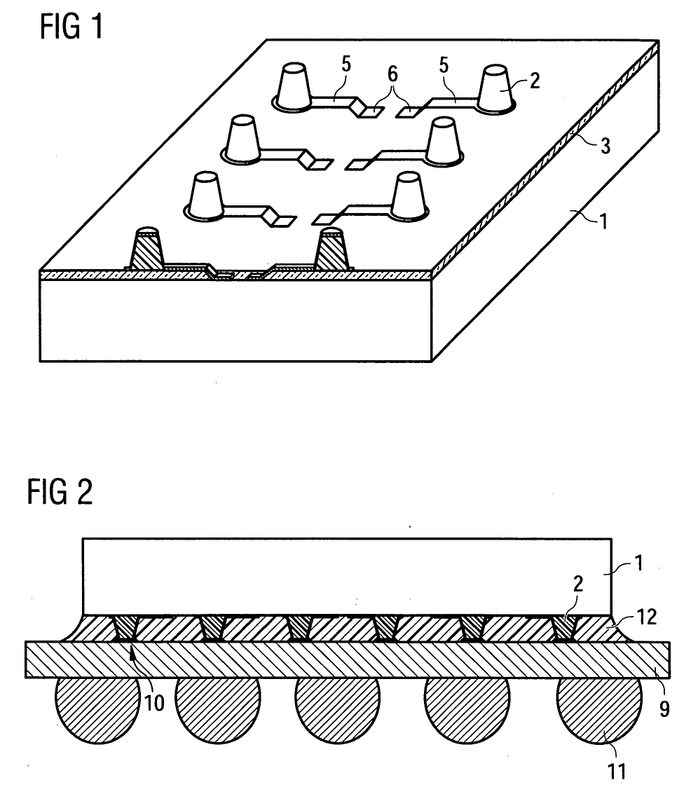

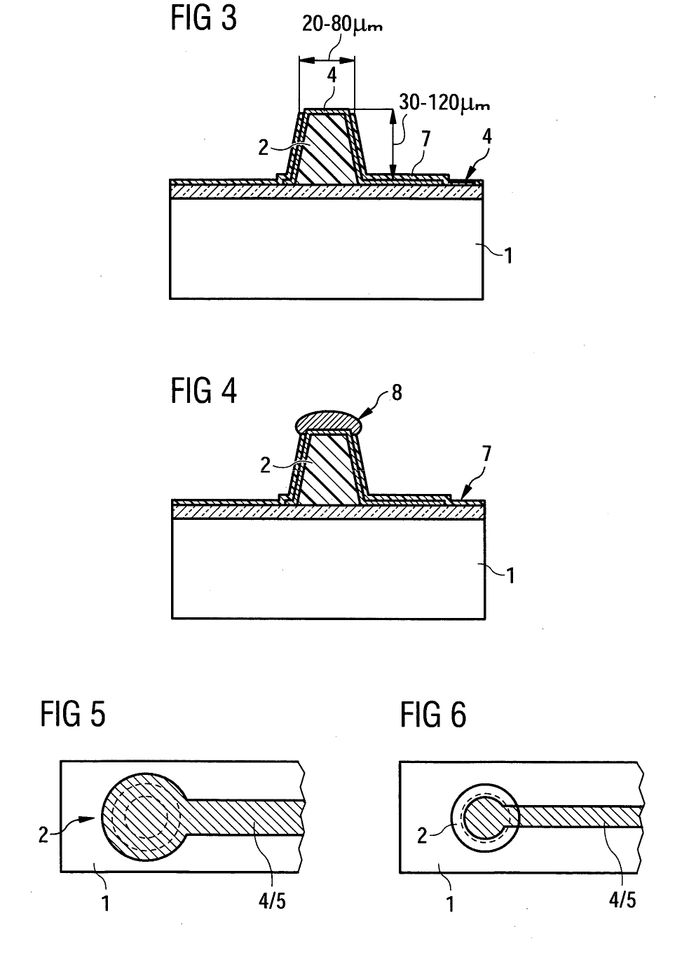

FIG. 1 firstly shows a schematic representation of a chip 1, which is provided with flexible elevations 2 (polymer pillar bumps) and a passivation layer 3. The flexible elevations are preferably formed as truncated cones and have a height of about 30-120 μm, with a diameter of about 20-80 μm. Furthermore, the flexible elevations 2 are provided completely (FIG. 5) or partly (FIG. 6) with a metallization, for example of Cu. The metallization 4 (shown in FIG. 3) is electrically connected by means of interconnects 5 (wiring interposers) in each case to the associated pad 6 on the chip 1. The Cu metallization may be produced by sputtering a seed layer and subsequent electroplating of a Cu layer. Furthermore, the active surface of the chip 1 is provided with a chip wiring interposer layer, which has at least one insulating layer with a low-k material.

FIG. 3 shows a detail of a chip with a flexible elevation 2, which is provided with a metallization 4. Additionally provided on the flexible elevations 2 and on the chip 1 is a solder resist layer 7, which leaves the upper surface of the frustoconical elastic elevation 2 free. In addition, a solder depot 8 may be provided on the flexible elevation 2, as can be seen from FIG. 4. This solder resist layer reliably prevents solder material from the solder depot 8 from being able to flow off the flexible elevations 2 during a soldering process and possibly being able to cause a short-circuit with respect to neighboring structures.

In FIG. 2, the chip 1 is then shown after the flip chip contacting (e.g., soldering, adhesive bonding, pressure contacting) on a substrate 9. The arrangement of the flexible elevations on the chip 1 in a grid pattern corresponds in this case to the grid pattern of contact pads/soldered connections 10, which are schematically indicated on the substrate 9 in FIG. 2. Furthermore, the contact pads 10 on the chip side of the substrate 9 are provided with contact balls 11 on the opposite side for mounting on printed circuit boards.

To realize an adequately solid connection between the chip 1 and the substrate 9, the intermediate space between the two elements and between the flexible elevations 2 is filled with an underfiller 12 (underfilling material). The modulus of elasticity of the underfiller 12 should be below about 5 GPa and the modulus of elasticity of the flexible elevation should be between I and 5 GPa, typically between 1 and 2 GPa. It is important for the invention that the elastic elevations 2 have a substantially frustoconical form and that the moduli of elasticity of the components to be joined to one another, including the low-k layer, are made to match one another.

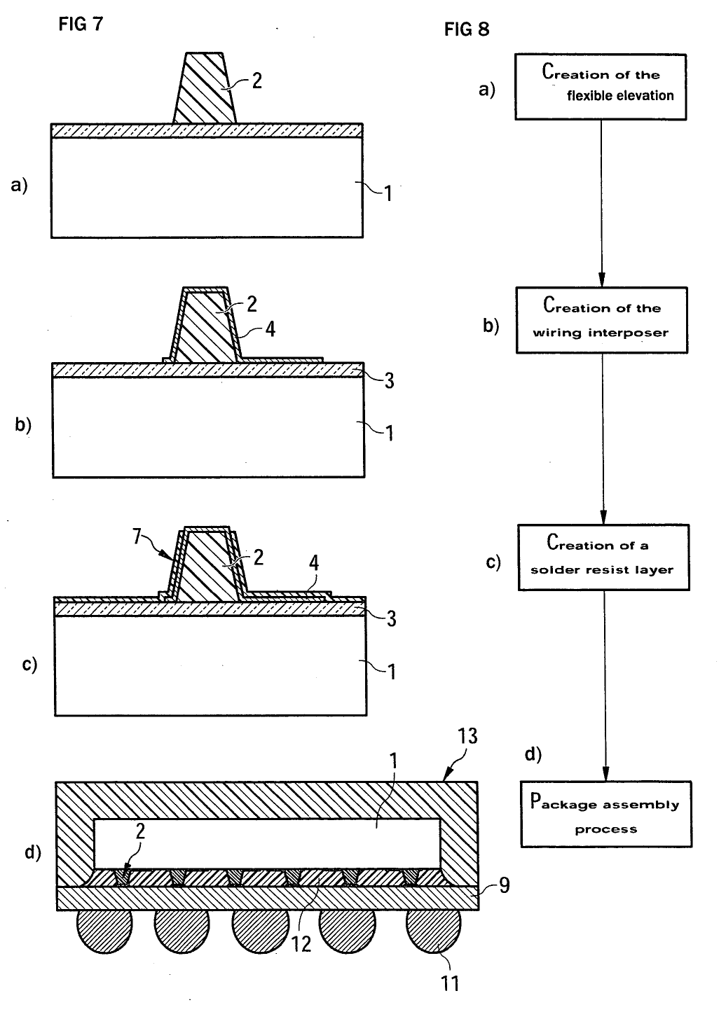

The process flow for producing the flexible elevations and the final assembly to form a flip chip in package is schematically represented in FIGS. 7a-7d and corresponding flow chart FIGS. 8a-8d.

Firstly, the chip 1 is passivated with a passivation layer 3, leaving the pads 6 free (the pads are shown in FIG. 1). Then, flexible elevations 2 (bumps) are produced on this passivation layer 3 in a predetermined grid pattern, for example by photolithographic patterning, printing (e.g., screen printing, jet printing or other suitable methods), molding or pick and place prefabricated structures (FIGS. 7a, 8a, creation of the flexible elevations). SU8, polyimide or other materials with a modulus of elasticity of <1-2 GPa come into consideration for the flexible elevations 2.

Subsequently, the flexible elevations 2 are at least partly metallized and electrically connected to the pad 6 belonging to the respective flexible elevation 2 by means of a wiring interposer. For the metallization with a layer thickness of 3-5 μm, various methods are available, such as sputtering of the seed layer, ED-photoresist plating with subsequent polylithographic patterning and subsequent electroplating of the wiring interposer/metallization.

After that, the solder resist layer 7 is applied to the chip 1, or at least to the metallization, by spray coating or patterning by means of photolithography with subsequent curing of the solder resist layer, for example in an annealing process. In this case, the tip of the flexible elevation 2 (the upper surface of the truncated cone) must of course be kept free of solder resist (FIGS. 7c, 8c, creation of the solder resist layer).

Represented in FIGS. 7d, 8d (final assembly/package assembly process), finally, is the finished flip chip in package, in which the flexible elevations 2 have firstly been provided with a flux and the chip 1 has been mounted on the substrate by flip chip bonding, followed by a reflow process. After that, the underfiller 12 was introduced and the necessary mechanical connection consequently realized. Until then, the structure corresponds to FIG. 2. To conclude, the chip side of the substrate 9 is encapsulated with a molding compound, so that a mold cap 13 is created.

What is claimed is:

1. An electronic component comprising:
a substrate having contacts;
a chip having contacts and a passivation layer disposed on an active side of the chip, wherein the active side of the chip is mounted on a first surface of the substrate by flip chip technology such that the contacts of the chip are electrically connected to the contacts of the substrate by means of connecting elements;
elastic elevations disposed between the contacts of the chip and the contacts of the substrate; and
an underfiller disposed in an intermediate space between the chip and the substrate and between the elastic elevations, the underfiller having a modulus of elasticity that is substantially the same as a modulus of elasticity of the elastic elevations.

2. The electronic component of claim 1, further comprising solder balls disposed on a second surface of the substrate, the second surface opposed to the first surface, wherein the contacts of the substrate are electrically coupled to the solder balls via ball pads.

3. The electronic component of claim 2, wherein the contacts of the substrate are electrically connected to the ball pads by means of wiring on the second surface of the substrate.

4. The electronic component of claim 1, wherein the elastic elements are provided at least partly with a metallization.

5. The electronic component of claim 4, wherein the metallization has a layer thickness between about 3 μm and about 5 μm.

6. The electronic component of claim 1, wherein the underfiller has a modulus of elasticity that is less than about 5 GPa.

7. The electronic component of claim 6, wherein the underfiller has a modulus of elasticity between about 1 GPa and about 2 GPa.

8. The electronic component of claim 1, wherein the elastic elevations comprise truncated cones.

9. The electronic component of claim 8, wherein the elastic elevations have a height between about 30 μm and about 120 μm and have an average thickness of between about 20 μm and about 30 μm.

10. The electronic component of claim 1, further comprising a solder resist that is applied to the chip and a portion of each elastic elevation such that an upper surface of each elastic elevation is free from solder resist.

11. The electronic component of claim 1, further comprising a solder material disposed on each elastic elevation.

12. A flip chip in package that includes a chip with contacts and a passivation layer on its active side, and also a substrate, on which the chip is mounted by flip chip technology and is electrically connected to contact pads of the substrate by means of connecting elements, the contact pads of the substrate being connected by means of wiring to ball pads on the side of the substrate opposite from the chip mounting side and in which solder balls are mounted on the ball pads, wherein elastic elevations are arranged as electrical connections between the chip and the substrate on the active side of the chip and wherein an underfiller is introduced into an intermediate space between the chip and the substrate and between the elastic elevations, the underfiller having a modulus of elasticity that is substantially the same as a modulus of elasticity of the elastic elevations.

13. The flip chip in package as claimed in claim 12, wherein the elastic elements are provided at least partly with a metallization.

14. The flip chip in package as claimed in claim 12, wherein the modulus of elasticity of the underfiller is less than about <5 GPa.

15. The flip chip in package as claimed in claim 12, wherein the elastic elevations comprise truncated cones.

16. A method of packaging a semiconductor chip, the method comprising:
providing a semiconductor chip;
forming a plurality of flexible elevations over an active surface of the semiconductor chip;
forming a conductive layer over the active surface, the conductive layer electrically connecting circuitry of the semiconductor chip to the flexible elevations;
mounting the semiconductor chip onto a substrate such that the flexible elevations of the semiconductor chip align with and are electrically connected to contact pads on the substrate; and
applying an underfiller between the semiconductor chip and the substrate and between the flexible elevations, the underfiller having a modulus of elasticity that is substantially the same as a modulus of elasticity of the flexible elevations.

17. The method of claim 16, further comprising encapsulating the chip with a mold cap.

18. The method of claim 17, further comprising applying a solder material over the flexible elevations before mounting the semiconductor chip onto the substrate.

19. The method of claim 17, wherein the elastic elevations comprise truncated cones.

20. The method of claim 17, further comprising forming a passivation layer over the active surface of the semiconductor chip prior to forming the flexible elevations, the passivation layer including openings that expose electrical contacts of the semiconductor chip such that the conductive layer electrically connects the circuitry of the semiconductor chip to the flexible elevations through the electrical contacts.
